(19) United States
(12) Patent Application Publication
(10) Pub. No.: US 2024/0090211 A1
(43) Pub. Date: Mar. 14, 2024

(54) THREE-DIMENSIONAL SEMICONDUCTOR MEMORY DEVICE AND ELECTRONIC SYSTEM INCLUDING THE SAME

(71) Applicant: SAMSUNG ELECTRONICS CO., LTD., Suwon-si (TW)

(72) Inventors: Soyeon KIM, Suwon-si (KR); Sung-Min HWANG, Suwon-si (KR); Dong-Sik LEE, Suwon-si (KR); Seunghyun CHO, Suwon-si (KR); Bongtae PARK, Suwon-si (KR); Jae-Joo SHIM, Suwon-si (KR)

(21) Appl. No.: 18/135,349

(22) Filed: Apr. 17, 2023

(30) Foreign Application Priority Data
Sep. 13, 2022 (KR) 10-2022-0114956

(51) Int. Cl. H10B 41/27; H01L 23/528; H10B 41/10; H10B 41/35; H10B 43/10; H10B 43/27; H10B 43/35

(52) U.S. Cl. CPC H10B 41/27; H01L 23/5283; H10B 41/10; H10B 41/35; H10B 43/10; H10B 43/27; H10B 43/35; H10B 80/00

(57) ABSTRACT

A semiconductor memory device includes a gate stack structure including insulating layers, a lower selection line and word lines, the word lines including a first word line adjacent to the lower selection line and a second word line on the first word line, a memory channel structure penetrating the gate stack structure, a plurality of first contact plugs electrically connected to the first word line, a plurality of second contact plugs electrically connected to the second word line, a first conductive line connected to the plurality of first contact plugs, and a second conductive line connected to one of the plurality of second contact plugs.

### CROSS-REFERENCE TO RELATED APPLICATIONS

This U.S. non-provisional patent application claims priority under 35 U.S.C. § 119 to Korean Patent Application No. 10-2022-0114956, filed on Sep. 13, 2022, in the Korean Intellectual Property Office, the entire contents of which are hereby incorporated by reference.

### BACKGROUND

### 1. Field

The present disclosure relates to a semiconductor device and an electronic system including the same. a three-dimensional semiconductor memory device with improved reliability and integration density and an electronic system including the same.

### 2. Description of the Related Art

An electronic system requiring data storage may require a semiconductor device capable of storing high-capacity data. Thus, techniques for increasing a data storage capacity of a semiconductor device have been studied. For example, a semiconductor device including three-dimensionally arranged memory cells instead of two-dimensionally arranged memory cells has been suggested as one of the techniques of increasing the data storage capacity of the semiconductor device.

### SUMMARY

Embodiments are directed to a three-dimensional semiconductor memory device including a gate stack structure including insulating layers, a lower selection line and word lines, the word lines including a first word line adjacent to the lower selection line and a second word line on the first word line, a memory channel structure penetrating the gate stack structure, a plurality of first contact plugs electrically connected to the first word line, a plurality of second contact plugs electrically connected to the second word line, a first conductive line connected to the plurality of first contact plugs, and a second conductive line connected to one of the plurality of second contact plugs.

Embodiments may further provide a three-dimensional semiconductor memory device including a gate stack structure including insulating layers and word lines, the word lines including a first word line corresponding to a lowermost one of the word lines, and a second word line on the first word line, a memory channel structure penetrating the gate stack structure, a plurality of first contact plugs electrically connected to the first word line, a plurality of second contact plugs electrically connected to the second word line, a first conductive line connected to the plurality of first contact plugs; and a second conductive line connected to one of the plurality of second contact plugs.

Embodiments may further provide an electronic system including a main board, a three-dimensional semiconductor memory device on the main board, and a controller disposed on the main board and electrically connected to the semiconductor memory device, wherein the semiconductor memory device includes a gate stack structure including insulating layers, a lower selection line, word lines and a dummy line, the word lines including a first word line adjacent to the lower selection line and a second word line on the first word line, a memory channel structure penetrating the gate stack structure, a plurality of first contact plugs electrically connected to the first word line, a plurality of second contact plugs electrically connected to the second word line, a plurality of third contact plugs electrically connected to the lower selection line, a plurality of dummy contact plugs electrically connected to the dummy line, a first conductive line connected to the plurality of first contact plugs, a second conductive line connected to one of the plurality of second contact plugs, a third conductive line connected to the plurality of third contact plugs; and a dummy conductive line connected to the plurality of dummy contact plugs.

### BRIEF DESCRIPTION OF THE DRAWINGS

Features will become apparent to those of skill in the art by describing in detail exemplary embodiments with reference to the attached drawings in which:

FIG. 1 is a schematic view illustrating an electronic system including a three-dimensional semiconductor memory device according to some embodiments.

FIG. 2 is a perspective view schematically illustrating an electronic system including a semiconductor memory device according to some embodiments.

FIGS. 3 and 4 are cross-sectional views taken along lines I-I′ and II-II′ of FIG. 2, respectively, to illustrate a semiconductor package including a semiconductor memory device according to some embodiments.

FIG. 5A is a plan view illustrating a semiconductor memory device according to some embodiments.

FIG. 5B is a cross-sectional view taken along a line A-A′ of FIG. 5A.

FIG. 6A is a cross-sectional view taken along a line B-B′ of FIG. 5A.

FIG. 6B is a cross-sectional view taken along a line C-C′ of FIG. 5A.

FIG. 6C is a cross-sectional view taken along a line D-D′ of FIG. 5A.

FIG. 7A is a plan view illustrating a semiconductor memory device according to some embodiments.

FIG. 7B is an enlarged plan view of a portion ‘P’ of FIG. 7A.

FIG. 8A is a plan view illustrating a semiconductor memory device according to some embodiments.

FIG. 8B is a plan view illustrating a semiconductor memory device according to some embodiments.

FIG. 8C is a plan view illustrating a semiconductor memory device according to some embodiments.

### DETAILED DESCRIPTION

Example embodiments will now be described more fully hereinafter with reference to the accompanying drawings. However, they may be embodied in different forms and should not be construed as limited to the embodiments set forth herein.

Embodiments may provide a three-dimensional semiconductor memory device with improved integration density and reliability, and an electronic system including the same.

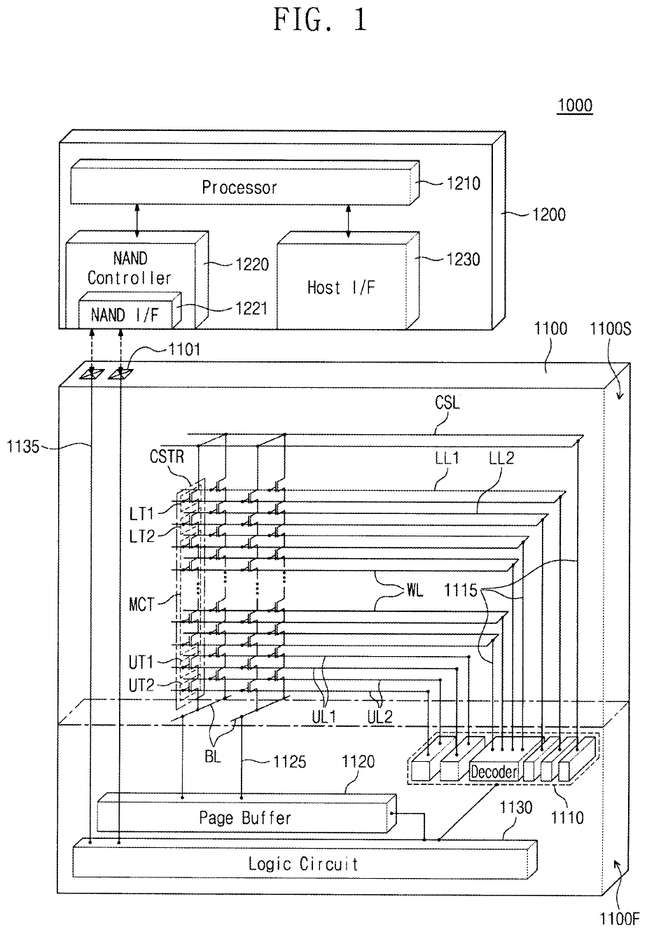

FIG. 1 is a schematic view illustrating an electronic system including a three-dimensional semiconductor memory device according to some embodiments.

Referring to FIG. 1, an electronic system 1000 according to some embodiments may include a three-dimensional semiconductor memory device 1100 and a controller 1200 electrically connected to the semiconductor memory device 1100. The electronic system 1000 may be a storage device including one or more semiconductor memory devices 1100, or an electronic device including the storage device. For example, the electronic system 1000 may be a solid state drive (SSD) device, a universal serial bus (USB) device, a computing system, a medical device or a communication device that includes the one or more semiconductor memory devices 1100.

The semiconductor memory device 1100 may be a non-volatile memory device. For example, the semiconductor memory device 1100 may be a three-dimensional NAND flash memory device to be described later. The semiconductor memory device 1100 may include a first region 1100F and a second region 1100S on the first region 1100F. As an alternative to what is shown in FIG. 1, the first region 1100F may be disposed at a side of the second region 1100S. The first region 1100F may be a peripheral circuit region including a decoder circuit 1110, a page buffer 1120 and a logic circuit 1130. The second region 1100S may be a memory cell region including bit lines BL, a common source line CSL, word lines WL, first lines LL1 and LL2, second lines UL1 and UL2, and memory cell strings CSTR between the common source line CSL and the bit lines BL.

In the second region 1100S, each of the memory cell strings CSTR may include first transistors LT1 and LT2 adjacent to the common source line CSL, second transistors UT1 and UT2 adjacent to the bit lines BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously changed. The memory cell strings CSTR may be located between the common source line CSL and the first region 1100F.

For example, the second transistors UT1 and UT2 may include a string selection transistor, and the first transistors LT1 and LT2 may include a ground selection transistor. The first lines LL1 and LL2 may be gate electrodes of the first transistors LT1 and LT2. The word lines WL may be gate electrodes of the memory cell transistors MCT, and the second lines UL1 and UL2 may be gate electrodes of the second transistors UT1 and UT2.

For example, the first transistors LT1 and LT2 may include a first erase control transistor LT1 and a ground selection transistor LT2, which are connected in series to each other. For example, the second transistors UT1 and UT2 may include a string selection transistor UT1 and a second erase control transistor UT2, which are connected in series to each other. At least one of the first erase control transistor LT1 or the second erase control transistor UT2 may be used in an erase operation of erasing data stored in the memory cell transistors MCT by using a gate induced drain leakage (GIDL) phenomenon.

The common source line CSL, the first lines LL1 and LL2, the word lines WL and the second lines UL1 and UL2 may be electrically connected to the decoder circuit 1110 through first connection lines 1115 extending from the inside of the first region 1100F into the second region 1100S. The bit lines BL may be electrically connected to the page buffer 1120 through second connection lines 1125 extending from the inside of the first region 1100F into the second region 1100S.

In the first region 1100F, the decoder circuit 1110 and the page buffer 1120 may perform a control operation on at least one selected from the plurality of memory cell transistors MCT. The decoder circuit 1110 and the page buffer 1120 may be controlled by the logic circuit 1130. The semiconductor memory device 1100 may communicate with the controller 1200 through an input/output pad 1101 electrically connected to the logic circuit 1130. The input/output pad 1101 may be electrically connected to the logic circuit 1130 through an input/output connection line 1135 extending from the inside of the first region 1100F into the second region 1100S.

The controller 1200 may include a processor 1210, a NAND controller 1220, and a host interface 1230. In some embodiments, the electronic system 1000 may include a plurality of the semiconductor memory devices 1100, and the controller 1200 may control the plurality of semiconductor memory devices 1100.

The processor 1210 may control overall operations of the electronic system 1000 including the controller 1200. The processor 1210 may operate according to predetermined firmware and may control the NAND controller 1220 to access the semiconductor memory device 1100. The NAND controller 1220 may include a NAND interface 1221 for processing communication with the semiconductor memory device 1100. A control command for controlling the semiconductor memory device 1100, data to be written in the memory cell transistors MCT of the semiconductor memory device 1100, and data to be read from the memory cell transistors MCT of the semiconductor memory device 1100 may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

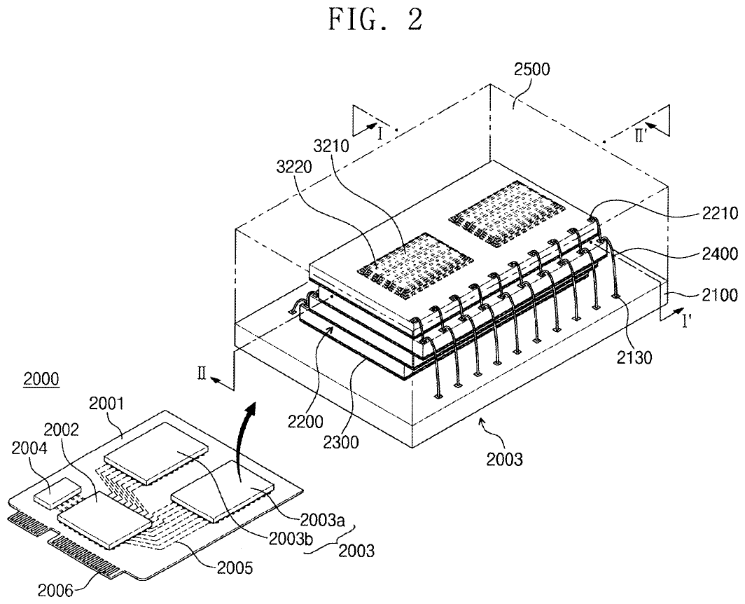

FIG. 2 is a perspective view schematically illustrating an electronic system including a semiconductor memory device according to some embodiments.

Referring to FIG. 2, an electronic system 2000 according to some embodiments may include a main board 2001 and a controller 2002, one or more semiconductor packages 2003 and a DRAM 2004 which are mounted on the main board 2001. The semiconductor package 2003 and the DRAM 2004 may be electrically connected to the controller 2002 through wiring patterns 2005 provided at the main board 2001.

The main board 2001 may include a connector 2006 including a plurality of pins capable of being coupled to an external host. The number and arrangement of the plurality of pins in the connector 2006 may be changed according to a communication interface between the electronic system 2000 and the external host. For example, the electronic system 2000 may communicate with the external host through one of a universal serial bus (USB) interface, a peripheral component interconnect express (PCI-express) interface, a serial advanced technology attachment (SATA) interface, and an M-Phy interface for a universal flash storage (UFS). For example, the electronic system 2000 may operate by power supplied from the external host through the connector 2006. The electronic system 2000 may further include a power management integrated circuit (PMIC) for distributing the power supplied from the external host to the controller 2002 and the semiconductor package 2003.

The controller 2002 may write data in the semiconductor package 2003 and/or read data from the semiconductor package 2003 and may improve an operation speed of the electronic system 2000.

The DRAM 2004 may be a buffer memory for reducing a speed difference between the external host and the semiconductor package 2003 corresponding to a data storage space. The DRAM 2004 included in the electronic system 2000 may also operate as a cache memory and may provide a space for temporarily storing data in an operation of controlling the semiconductor package 2003. In the case in which the electronic system 2000 includes the DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on bottom surfaces of the semiconductor chips 2200, respectively, connection structures 2400 electrically connecting the semiconductor chips 2200 to the package substrate 2100, and a molding layer 2500 covering the semiconductor chips 2200 and the connection structures 2400 on the package substrate 2100.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stack structures 3210 and memory channel structures 3220. Each of the semiconductor chips 2200 may include a semiconductor memory device as described later.

For example, the connection structures 2400 may be bonding wires electrically connecting the input/output pads 2210 to the package upper pads 2130. Thus, in each of the first and second semiconductor packages 2003a and 2003b, the semiconductor chips 2200 may be electrically connected to each other and be electrically connected to the package upper pads 2130 of the package substrate 2100 by a wire bonding method. According to certain embodiments, in each of the first and second semiconductor packages 2003a and 2003b, the semiconductor chips 2200 may be electrically connected to each other through through-electrodes (e.g., through silicon vias), instead of the connection structures 2400 of the wire bonding method.

As an alternative to what is shown in FIG. 2, the controller 2002 and the semiconductor chips 2200 may be included in a single package. In this case, the controller 2002 and the semiconductor chips 2200 may be mounted on an interposer substrate different from the main board 2001, and the controller 2002 and the semiconductor chips 2200 may be connected to each other by wiring lines provided at the interposer substrate.

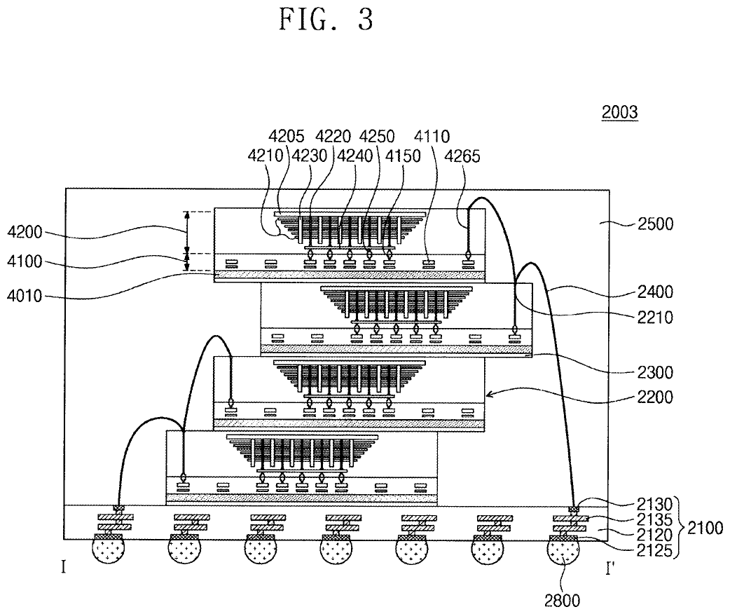

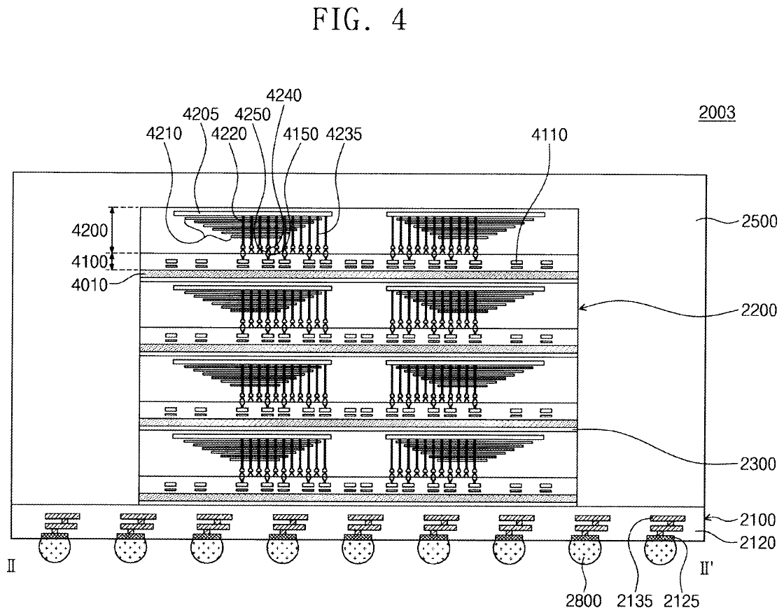

FIGS. 3 and 4 are cross-sectional views taken along lines I-I′ and II-II′ of FIG. 2, respectively, to illustrate a semiconductor package including a semiconductor memory device according to some embodiments.

Referring to FIGS. 3 and 4, the semiconductor package 2003 may include the package substrate 2100, a plurality of the semiconductor chips 2200 on the package substrate 2100, and the molding layer 2500 covering the package substrate 2100 and the semiconductor chips 2200.

The package substrate 2100 may include a package substrate body portion 2120, the package upper pads 2130 disposed on or exposed at a top surface of the package substrate body portion 2120, package lower pads 2125 disposed on or exposed at a bottom surface of the package substrate body portion 2120, and internal wiring lines 2135 electrically connecting the package upper pads 2130 to the package lower pads 2125 in the package substrate body portion 2120. The package upper pads 2130 may be electrically connected to the connection structures 2400. The package lower pads 2125 may be connected to the wiring patterns 2005 of the main board 2001 of the electronic system 2000 shown in FIG. 2 through conductive connection portions 2800.

Referring to FIGS. 2 and 3, some side surfaces of the semiconductor chips 2200 may not be aligned with each other, and other side surfaces of the semiconductor chips 2200 may be aligned with each other. The semiconductor chips 2200 may be electrically connected to each other through the connection structures 2400 having bonding wire shapes. The semiconductor chips 2200 may include substantially the same components.

Each of the semiconductor chips 2200 may include a semiconductor substrate 4010, a first structure 4100 on the semiconductor substrate 4010, and a second structure 4200 on the first structure 4100. The second structure 4200 may be coupled to the first structure 4100 by a wafer bonding method.

The first structure 4100 may include peripheral circuit interconnection lines 4110 and first bonding pads 4150. The second structure 4200 may include a common source line 4205, a gate stack structure 4210 between the common source line 4205 and the first structure 4100, memory channel structures 4220 and separation structures 4230 that penetrate the gate stack structure 4210, and second bonding pads 4250 electrically connected to the memory channel structures 4220 and word lines (see WL of FIG. 1) of the gate stack structure 4210, respectively. For example, the second bonding pads 4250 may be electrically connected to the memory channel structures 4220 and the word lines (see WL of FIG. 1) through bit lines 4240 electrically connected to the memory channel structures 4220 and gate connection lines 4235 electrically connected to the word lines (see WL of FIG. 1), respectively. The first bonding pads 4150 of the first structure 4100 may be in contact with and bonded to the second bonding pads 4250 of the second structure 4200. For example, the bonded portions of the first bonding pads 4150 and the second bonding pads 4250 may include copper (Cu).

Each of the semiconductor chips 2200 may further include an input/output pad 2210 and an input/output connection line 4265 under the input/output pad 2210. The input/output connection line 4265 may be electrically connected to at least one of the second bonding pads 4250 and at least one of the peripheral circuit interconnection lines 4110.

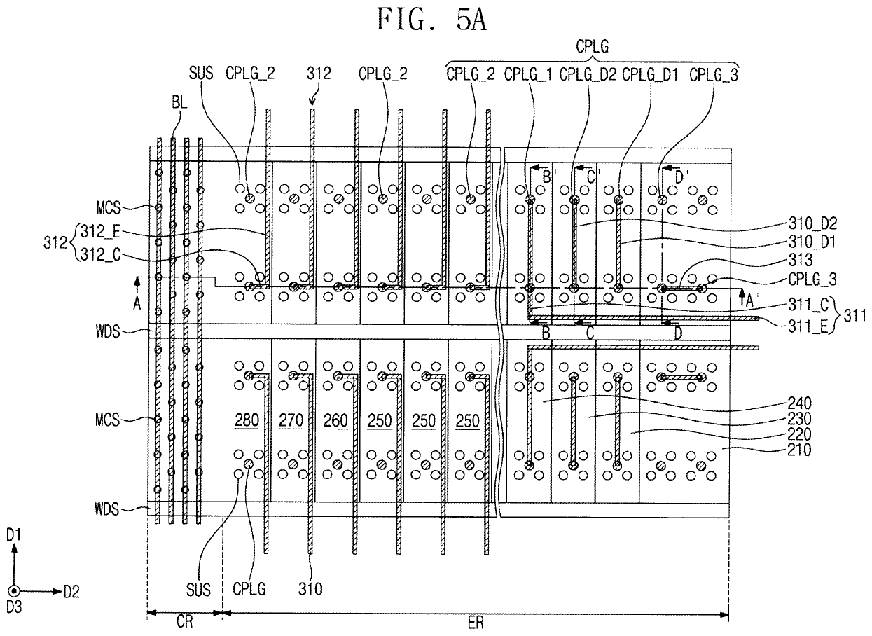

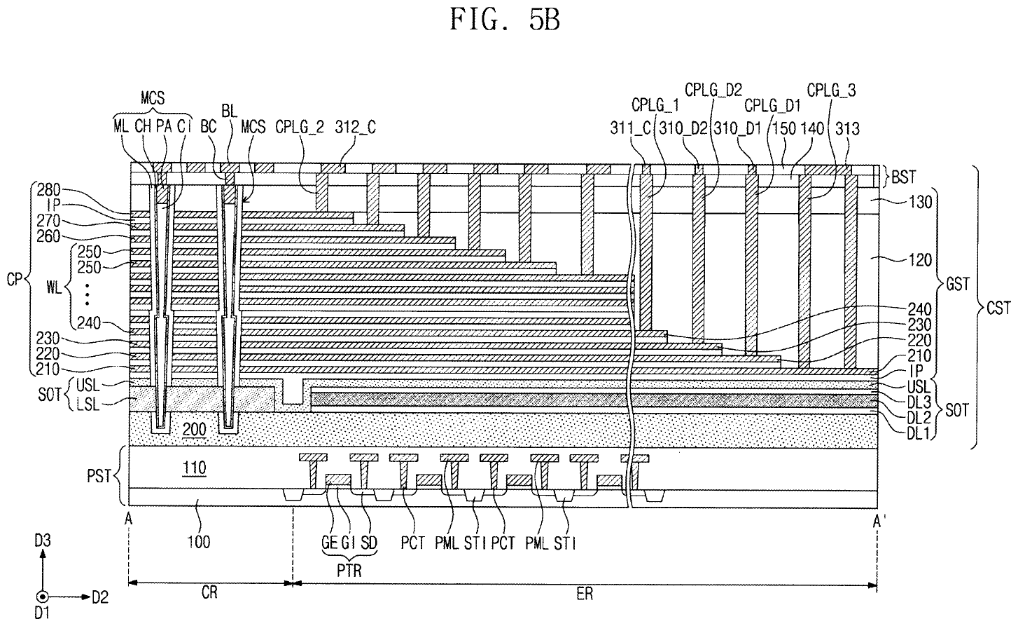

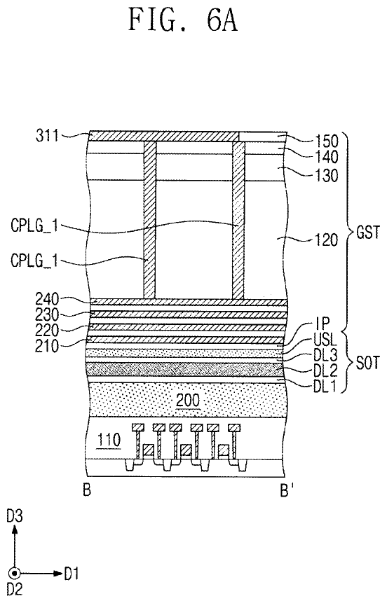

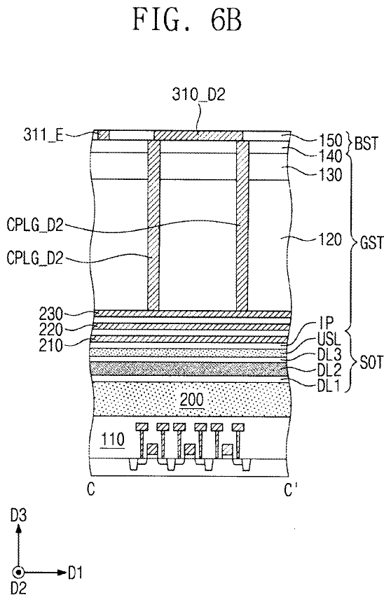

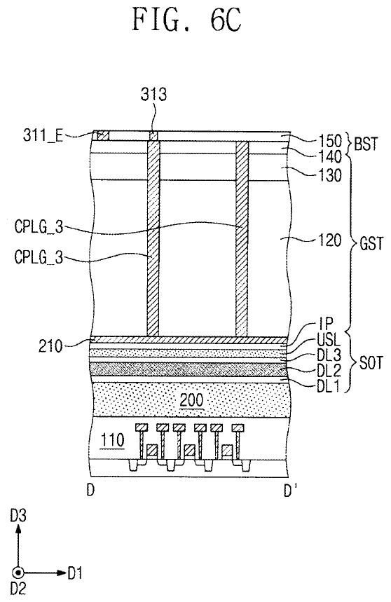

FIG. 5A is a plan view illustrating a semiconductor memory device according to some embodiments. FIG. 5B is a cross-sectional view taken along a line A-A′ of FIG. 5A. FIG. 6A is a cross-sectional view taken along a line B-B′ of FIG. 5A. FIG. 6B is a cross-sectional view taken along a line C-C′ of FIG. 5A. FIG. 6C is a cross-sectional view taken along a line D-D′ of FIG. 5A.

Referring to FIGS. 5A, 5B and 6A to 6C, a semiconductor memory device according to some embodiments may include a peripheral circuit structure PST and a memory cell structure CST. The memory cell structure CST may be provided on the peripheral circuit structure PST.

The peripheral circuit structure PST may include a substrate 100. The substrate 100 may have a plate shape extending along a plane defined by a first direction D1 and a second direction D2. The first direction D1 and the second direction D2 may intersect each other. For example, the first direction D1 and the second direction D2 may be perpendicular to each other. In some embodiments, the substrate 100 may be a semiconductor substrate. For example, the substrate 100 may be a silicon substrate. In some embodiments, the substrate 100 may be a silicon-on-insulator (SOI) substrate.

The substrate 100 may include a cell region CR and an extension region ER. The cell region CR and the extension region ER of the substrate 100 may be regions that are distinguishable from each other when viewed in a plan view defined by the first direction D1 and the second direction D2.

The peripheral circuit structure PST may further include a peripheral insulating layer 110 covering the substrate 100. The peripheral insulating layer 110 may cover a top surface of the substrate 100. The peripheral insulating layer 110 may include an insulating material. For example, the peripheral insulating layer 110 may include an oxide. In some embodiments, the peripheral insulating layer 110 may include a plurality of stacked insulating layers.

The peripheral circuit structure PST may further include peripheral transistors PTR. The peripheral transistors PTR may be provided between the substrate 100 and the peripheral insulating layer 110. The peripheral transistors PTR may include source/drain regions SD, a gate electrode GE, and a gate insulating layer GI. The gate electrode GE and the gate insulating layer GI may be provided on the substrate 100 between the source/drain regions SD. The gate electrode GE may be spaced apart from the substrate 100 by the gate insulating layer GI. The source/drain regions SD may be formed by doping portions of the substrate 100 with dopants. The gate electrode GE may include a conductive material. The gate insulating layer GI may include an insulating material.

The peripheral circuit structure PST may further include a device isolation layer STI. The device isolation layer STI may be provided in the substrate 100. The device isolation layer STI may be disposed between the peripheral transistors PTR to electrically isolate the peripheral transistors PTR from each other. The device isolation layer STI may include an insulating material.

The peripheral circuit structure PST may further include peripheral contacts PCT and peripheral interconnection lines PML. The peripheral contact PCT may be connected to the peripheral transistor PTR, and the peripheral interconnection line PML may be connected to the peripheral contact PCT. The peripheral contact PCT and the peripheral interconnection line PML may be provided in the peripheral insulating layer 110. The peripheral contact PCT and the peripheral interconnection line PML may include a conductive material.

The memory cell structure CST may include a semiconductor layer 200, a source structure SOT, a gate stack structure GST, memory channel structures MCS, support structures SUS, separation structures WDS, first contact plugs CPLG_1, second contact plugs CPLG_2, and a bit line structure BST.

The semiconductor layer 200 may be disposed on the peripheral insulating layer 110 of the peripheral circuit structure PST. The semiconductor layer 200 may include an extrinsic semiconductor material doped with dopants and/or an intrinsic semiconductor material not doped with dopants. For example, the semiconductor layer 200 may include at least one of silicon (Si), germanium (Ge), silicon-germanium (SiGe), gallium arsenic (GaAs), indium gallium arsenic (InGaAs), aluminum gallium arsenic (AlGaAs), or a mixture thereof.

The source structure SOT may be provided on the semiconductor layer 200. The source structure SOT may include a lower source layer LSL, an upper source layer USL, a first dummy source layer DL1, a second dummy source layer DL2, and a third dummy source layer DL3. The lower source layer LSL, the upper source layer USL, the first dummy source layer DL1, the second dummy source layer DL2 and the third dummy source layer DL3 may be provided on the semiconductor layer 200.

The lower source layer LSL may be provided on the semiconductor layer 200. The lower source layer LSL may be disposed on the cell region CR. The lower source layer LSL may include a conductive material. For example, the lower source layer LSL may include dopant-doped poly-silicon.

The first dummy source layer DL1, the second dummy source layer DL2 and the third dummy source layer DL3 may be sequentially stacked on the semiconductor layer 200 in a third direction D3. The third direction D3 may intersect the first direction D1 and the second direction D2. For example, the third direction D3 may be perpendicular to the first direction D1 and the second direction D2.

The first to third dummy source layers DL1, DL2 and DL3 may be disposed on the extension region ER. The first to third dummy source layers DL1, DL2 and DL3 may be located at the same level as the lower source layer LSL. The first to third dummy source layers DL1, DL2 and DL3 may include an insulating material. In some embodiments, the first and third dummy source layers DL1 and DL3 may include the same insulating material, and the second dummy source layer DL2 may include an insulating material different from that of the first and third dummy source layers DL1 and DL3. For example, the second dummy source layer DL2 may include silicon nitride, and the first and third dummy source layers DL1 and DL3 may include silicon oxide.

The upper source layer USL may cover the lower source layer LSL and the first to third dummy source layers DL1, DL2 and DL3. The upper source layer USL may extend from the cell region CR onto the extension region ER. The upper source layer USL may include a semiconductor material. For example, the upper source layer USL may include dopant-doped poly-silicon or undoped poly-silicon.

The gate stack structure GST may be provided on the source structure SOT. The gate stack structure GST may include insulating layers IP and conductive patterns CP, which are alternately stacked in the third direction D3. The gate stack structure GST may include a gate insulating layer 120 on the insulating layers IP and the conductive patterns CP which are alternately stacked. The gate stack structure GST may include a first insulating layer 130 on the gate insulating layer 120. The insulating layers IP may include an insulating material. For example, the insulating layers IP may include an oxide. The conductive patterns CP may include a conductive material. For example, the conductive patterns CP may include at least one of doped poly-silicon, a metal, or a metal nitride.

The conductive patterns CP may include a lower selection line 210, a first dummy line 220 on the lower selection line 210, a second dummy line 230 on the first dummy line 220, word lines WL on the second dummy line 230, a third dummy line 260 on the word lines WL, a fourth dummy line 270 on the third dummy line 260, and an upper selection line 280 on the fourth dummy line 270.

The word lines WL may include a first word line 240 and second word lines 250 on the first word line 240. The first word line 240 may be adjacent to the lower selection line 210. A lowermost one of the word lines WL may be defined as the first word line 240. The word lines WL disposed at higher levels than the first word line 240 may be defined as the second word lines 250.

The conductive patterns CP and the insulating layers IP of the gate stack structure GST may include a staircase shape which becomes lower as a distance of the gate stack structure GST from the memory channel structure MCS increases.

The memory channel structures MCS may be disposed on the cell region CR. The memory channel structures MCS may extend in the third direction D3 to penetrate the conductive patterns CP and the insulating layers IP of the gate stack structure GST and the upper source layer USL and the lower source layer LSL of the source structure SOT. The memory channel structures MCS may penetrate the gate stack structure GST so as to be electrically connected to the source structure SOT of the cell region CR. The memory channel structures MCS may be surrounded by the insulating layers IP and the conductive patterns CP of the gate stack structure GST. A lowermost portion of the memory channel structure MCS may be disposed in the semiconductor layer 200.

Each of the memory channel structures MCS may include a core insulating layer CI, a pad PA, a channel layer CH, and a memory layer ML. The core insulating layer CI may extend in the third direction D3 to penetrate the conductive patterns CP and the insulating layers IP of the gate stack structure GST and the upper source layer USL and the lower source layer LSL of the source structure SOT. The core insulating layer CI may include an insulating material. For example, the core insulating layer CI may include an oxide. The pad PA may be provided on the core insulating layer CI. The pad PA may include a conductive material.

The channel layer CH may surround the core insulating layer CI and the pad PA. The channel layer CH may extend in the third direction D3 to penetrate the conductive patterns CP and the insulating layers IP of the gate stack structure GST and the upper source layer USL and the lower source layer LSL of the source structure SOT. The channel layer CH may cover a side surface and a bottom surface of the core insulating layer CI. The channel layer CH may be in contact with the lower source layer LSL of the source structure SOT. The memory channel structure MCS may be electrically connected to the source structure SOT. The channel layer CH of the memory channel structure MCS may be electrically connected to the lower source layer LSL of the source structure SOT. The channel layer CH may include a semiconductor material. For example, the channel layer CH may include poly-silicon.

The memory layer ML may surround the channel layer CH. The memory layer ML may extend in the third direction D3 to penetrate the conductive patterns CP and the insulating layers IP of the gate stack structure GST. The memory layer ML may be surrounded by the conductive patterns CP and the insulating layers IP of the gate stack structure GST.

The support structures SUS may be disposed on the extension region ER. The support structures SUS may extend in the third direction D3 to penetrate the conductive patterns CP and the insulating layers IP of the gate stack structure GST and the upper source layer USL and the first to third dummy source layers DL1, DL2 and DL3 of the source structure SOT. The support structures SUS may penetrate the gate stack structure GST and may be connected to the source structure SOT of the extension region ER. The support structures SUS may include an insulating material. For example, the support structures SUS may include an oxide.

The support structures SUS may be surrounded by the conductive patterns CP and the insulating layers IP of the gate stack structure GST. A lowermost portion of the support structure SUS may be disposed in the semiconductor layer 200.

The separation structures WDS may extend from the cell region CR onto the extension region ER. The separation structures WDS may extend in the second direction D2. The separation structures WDS may penetrate the gate stack structure GST and may be connected to the source structure SOT. The separation structures WDS may extend in the third direction D3 to penetrate the conductive patterns CP and the insulating layers IP of the gate stack structure GST and the upper source layer USL, the first to third dummy source layers DL1, DL2 and DL3 and the lower source layer LSL of the source structure SOT. The separation structures WDS may include an insulating material. For example, the separation structures WDS may include an oxide. In some embodiments, the separation structure WDS may further include a conductive material. A lowermost portion of the separation structure WDS may be disposed in the semiconductor layer 200.

Contact plugs CPLG may be disposed on the extension region ER. The contact plugs CPLG may include the first contact plugs CPLG_1, the second contact plugs CPLG_2, third contact plugs CPLG_3, first dummy contact plugs CPLG_D1, and second dummy contact plugs CPLG_D2. The contact plugs CPLG may include a conductive material. For example, the contact plugs CPLG may include tungsten.

The first contact plugs CPLG_1 may be electrically connected to the first word line 240. The first contact plugs CPLG_1 may penetrate the first insulating layer 130. At least two first contact plugs CPLG_1 may be located between two separation structures WDS adjacent to each other. The first contact plugs CPLG_1 may be spaced apart from each other in the first direction D1.

The second contact plug CPLG_2 may be electrically connected to the second word line 250, the third dummy line 260, the fourth dummy line 270 or the upper selection line 280. The second contact plugs CPLG_2 may penetrate the first insulating layer 130. At least two second contact plugs CPLG_2 may be disposed between two separation structures WDS adjacent to each other and may be connected to one of the second word lines 250. The at least two second contact plugs CPLG_2 may be spaced apart from each other in the first direction D1. The second contact plugs CPLG_2 may be closer to the memory channel structure MCS than the first contact plugs CPLG_1. Vertical lengths of the first contact plugs CPLG_1 may be greater than those of the second contact plugs CPLG_2.

The first dummy contact plug CPLG_D1 may penetrate the first insulating layer 130. The second dummy contact plug CPLG_D2 may penetrate the first insulating layer 130. The first dummy contact plug CPLG_D1 may be electrically connected to the first dummy line 220. The second dummy contact plug CPLG_D2 may be electrically connected to the second dummy line 230. At least two first dummy contact plugs CPLG_D1 may be located between two separation structures WDS adjacent to each other. At least two second dummy contact plugs CPLG_D2 may be located between two separation structures WDS adjacent to each other. The at least two first dummy contact plugs CPLG_D1 may be spaced apart from each other in the first direction D1. The at least two second dummy contact plugs CPLG_D2 may be spaced apart from each other in the first direction D1. A vertical length of the first dummy contact plug CPLG_D1 may be greater than a vertical length of the second dummy contact plug CPLG_D2.

The third contact plug CPLG_3 may be electrically connected to the lower selection line 210. The third contact plug CPLG_3 may penetrate the first insulating layer 130. At least two third contact plugs CPLG_3 may be located between two separation structures WDS adjacent to each other. The at least two third contact plugs CPLG_3 may be spaced apart from each other in the first direction D1. The at least two third contact plugs CPLG_3 may be spaced apart from each other in the second direction D2. A vertical length of the third contact plug CPLG_3 may be greater than that of the first dummy contact plug CPLG_D1 or second dummy contact plug CPLG_D2.

The bit line structure BST may be provided on the gate stack structure GST. The bit line structure BST may include a second insulating layer 140, a third insulating layer 150, a bit line contact BC, a bit line BL, a first conductive line 311, a second conductive line 312, a third conductive line 313, a first dummy conductive line 310_D1, and a second dummy conductive line 310_D2.

The second insulating layer 140 may cover the gate stack structure GST, the memory channel structures MCS, and the support structures SUS. The second insulating layer 140 may cover top surfaces of the memory channel structures MCS and the support structures SUS.

The bit line contacts BC may be provided in the second insulating layer 140. The bit line contact BC may penetrate the second insulating layer 140 so as to be in contact with the pad PA of the memory channel structure MCS. The bit line contacts BC may include a conductive material.

The third insulating layer 150 may be provided to cover the second insulating layer 140 and the bit line contacts BC. The third insulating layer 150 may include an insulating material.

The bit lines BL may be provided in the third insulating layer 150. The bit lines BL may extend in the first direction D1. The bit lines BL may be spaced apart from each other in the second direction D2. The bit line BL may be electrically connected to the memory channel structure MCS through the bit line contact BC. The bit line BL may include a conductive material.

The first conductive line 311 may be connected to the at least two first contact plugs CPLG_1. The first conductive line 311 may include a first connection portion 311_C connected to the at least two first contact plugs CPLG_1. The first connection portion 311_C of the first conductive line 311 may extend in the first direction D1 to connect the at least two first contact plugs CPLG_1. The first conductive line 311, the first contact plugs CPLG_1 and the first word line 240 may be electrically connected to each other. The first conductive line 311 may be located between the two separation structures WDS adjacent to each other when viewed in a plan view.

The first conductive line 311 may further include a first extension portion 311_E. The first extension portion 311_E of the first conductive line 311 may be a portion extending in the second direction D2. The first extension portion 311_E of the first conductive line 311 may be closer to the separation structure WDS than the first connection portion 311_C of the first conductive line 311. The first conductive line 311 may overlap with the first word line 240, the first dummy line 220, the second dummy line 230, and the lower selection line 210.

The second conductive line 312 may be connected to one of the at least two second contact plugs CPLG_2. The second conductive line 312 may include a second connection portion 312_C connected to the second contact plug CPLG_2. The second connection portion 312_C of the second conductive line 312 may extend in the second direction D2 so as to be connected to the second contact plug CPLG_2. The second conductive line 312, the second contact plug CPLG_2 and the second word line 250 may be electrically connected to each other. The second conductive line 312 may be located between the bit line BL and the first conductive line 311 when viewed in a plan view.

The second conductive line 312 may further include a second extension portion 312_E. The second extension portion 312_E of the second conductive line 312 may be a portion extending in the first direction D1. The second extension portion 312_E of the second conductive line 312 may be connected to the second connection portion 312_C of the second conductive line 312.

The third conductive line 313 may be connected to a plurality of the third contact plugs CPLG_3. The third conductive line 313, the third contact plugs CPLG_3 and the lower selection line 210 may be electrically connected to each other.

The third conductive line 313 may be located between the plurality of third contact plugs CPLG_3. The third conductive line 313 may extend in the second direction D2 to connect the plurality of third contact plugs CPLG_3.

The first dummy conductive line 310_D1 may be electrically connected to a plurality of the first dummy contact plugs CPLG_D1. The first dummy conductive line 310_D1 may be located between the plurality of first dummy contact plugs CPLG_D1. The first dummy conductive line 310_D1 may extend in the first direction D1 to connect the plurality of first dummy contact plugs CPLG_D1.

The second dummy conductive line 310_D2 may be electrically connected to a plurality of the second dummy contact plugs CPLG_D2. The second dummy conductive line 310_D2 may be located between the plurality of second dummy contact plugs CPLG_D2. The second dummy conductive line 310_D2 may extend in the first direction D1 to connect the plurality of second dummy contact plugs CPLG_D2.

The first conductive line 311, the second conductive line 312, the third conductive line 313, the first dummy conductive line 310_D1 and the second dummy conductive line 310_D2 may be spaced apart from each other.

The first conductive line 311 may be connected to the at least two first contact plugs CPLG_1, and thus even though one of the at least two first contact plugs CPLG_1 is not in contact with the first word line 240, the first conductive line 311, the first contact plugs CPLG_1 and the first word line 240 may be electrically connected to each other because another of the at least two first contact plugs CPLG_1 is in contact with the first word line 240.

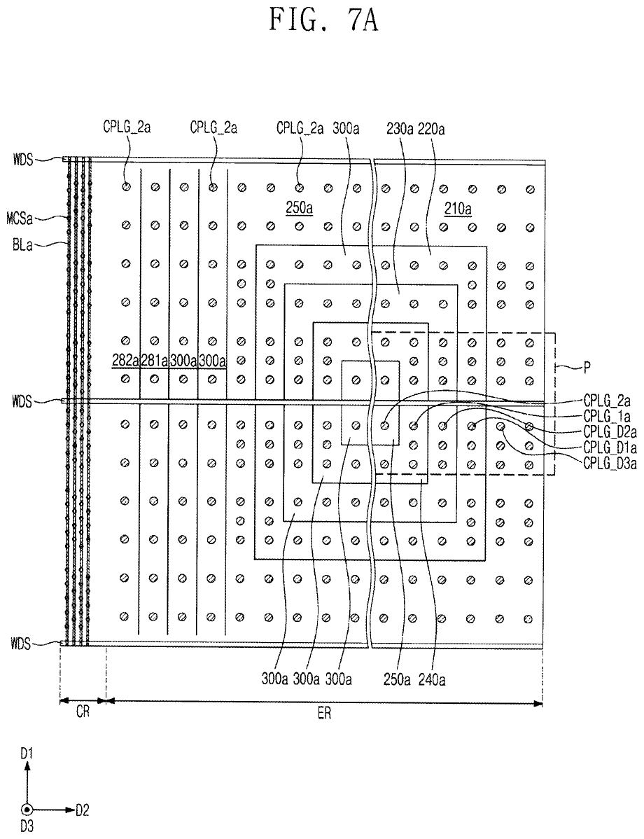

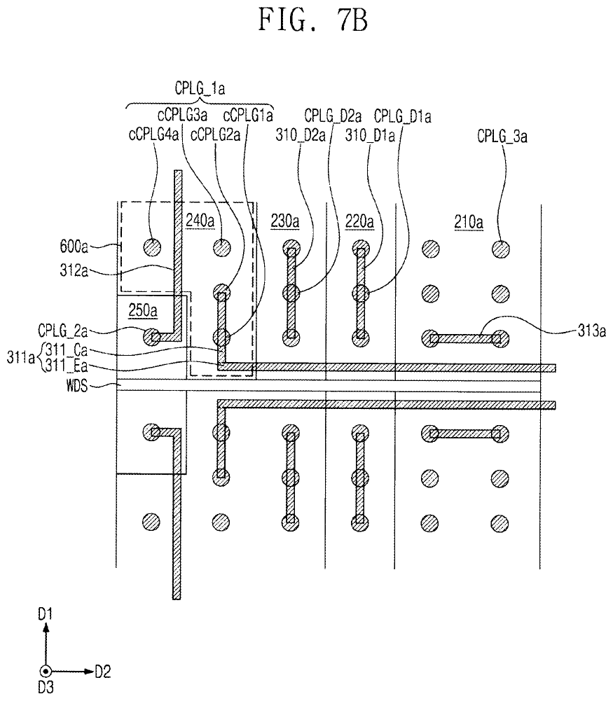

FIG. 7A is a plan view illustrating a three-dimensional semiconductor memory device according to some embodiments. FIG. 7B is an enlarged plan view of a portion ‘P’ of FIG. 7A.

Referring to FIGS. 7A and 7B, a three-dimensional semiconductor memory device according to some embodiments may include a substrate including a cell region CR and an extension region ER, and a separation structure WDS extending from the cell region CR onto the extension region ER. The semiconductor device according to the present embodiments may have a symmetrical structure with respect to the separation structure WDS.

The cell region CR may include a memory cell structure MCSa and a bit line BLa on the memory cell structure MCSa. The extension region ER may include a lower selection line 210a, a first dummy line 220a, a second dummy line 230a, a first word line 240a, a second word line 250a, upper dummy lines 300a, a first upper selection line 281a, and a second upper selection line 282a.

A plurality of third contact plugs CPLG_3a may be provided on the lower selection line 210a. A plurality of first dummy contact plugs CPLG_Dla may be provided on the first dummy line 220a. A plurality of second dummy contact plugs CPLG_D2a may be provided on the second dummy line 230a. A plurality of first contact plugs CPLG_la may be provided on the first word line 240a. Second contact plugs CPLG_2a may be provided on the second word line 250a, the upper dummy lines 300a, the first upper selection line 281a, and the second upper selection line 282a.

The first word line 240a may further include a corner portion 600a exposed by the second word line 250a. The corner portion 600a may be bent. The corner portion 600a may be an exposed portion of the first word line 240a, which is not covered by the second word line 250a. A plurality of the first contact plugs CPLG_1a may be provided on the corner portion 600a of the first word line 240a. The first contact plugs CPLG_la may be electrically connected to the corner portion 600a.

The first contact plugs CPLG_1a may include a first corner contact plug cCPLG1a, a second corner contact plug cCPLG2a, a third corner contact plug cCPLG3a, and a fourth corner contact plug cCPLG4a. The first corner contact plug cCPLG1a may be closest to the separation structure WDS among the first to fourth corner contact plugs cCPLG1a, cCPLG2a, cCPLG3a and cCPLG4a. The second corner contact plug cCPLG2a may be spaced apart from the first corner contact plug cCPLG1a in a first direction D1. The third corner contact plug cCPLG3a may be spaced apart from the second corner contact plug cCPLG2a in the first direction D1. The third corner contact plug cCPLG3a may be spaced apart from the fourth corner contact plug cCPLG4a in a second direction D2.

A distance between the first corner contact plug cCPLG1a and the second corner contact plug cCPLG2a may be less than a distance between the fourth corner contact plug cCPLG4a and the third corner contact plug cCPLG3a.

A plurality of the first contact plugs CPLG_la may be electrically connected to a first conductive line 311a. For example, the first conductive line 311a may include a first connection portion 311_Ca connected to the second corner contact plug cCPLG2a and the first corner contact plug cCPLG1a. The first connection portion 311_Ca of the first conductive line 311a may extend in the first direction D1 to connect the second corner contact plug cCPLG2a and the first corner contact plug cCPLG1a.

The first conductive line 311a may further include a first extension portion 311_Ea. The first extension portion 311_Ea of the first conductive line 311a may be a portion extending in the second direction D2. The first extension portion 311_Ea of the first conductive line 311a may be closer to the separation structure WDS than the first connection portion 311_Ca of the first conductive line 311a. The first conductive line 311a may not be electrically connected to the third corner contact plug cCPLG3a and the fourth corner contact plug cCPLG4a.

One of the second contact plugs CPLG_2a may be electrically connected to a second conductive line 312a. The second conductive line 312a may extend in the first direction D1, but embodiments are not limited thereto.

A plurality of the first dummy contact plugs CPLG_DIa may be electrically connected to a first dummy conductive line 310_D1a. For example, the first dummy conductive line 310_D1a may extend in the first direction D1 to connect three first dummy contact plugs CPLG_Dla.

Two or more of a plurality of the second dummy contact plugs CPLG_D2a may be electrically connected to a second dummy conductive line 310_D2a. For example, the second dummy conductive line 310_D2a may extend in the first direction D1 to connect three second dummy contact plugs CPLG_D2a.

Two or more of a plurality of the third contact plugs CPLG_3a may be electrically connected to a third conductive line 313a. The third conductive line 313a may extend in the second direction D2 to connect the third contact plugs CPLG_3a.

The first conductive line 311a, the second conductive line 312a and the third conductive line 313a may be spaced apart from each other. The number of the first contact plugs CPLG_1a per unit area of the corner portion 600a may be more than the number of the second contact plugs CPLG_2a per unit area of the second word line 250a.

The number of the first contact plugs CPLG_la between two separation structures WDS adjacent to each other may be different from the number of the second contact plugs CPLG_2a between the two separation structures WDS adjacent to each other.

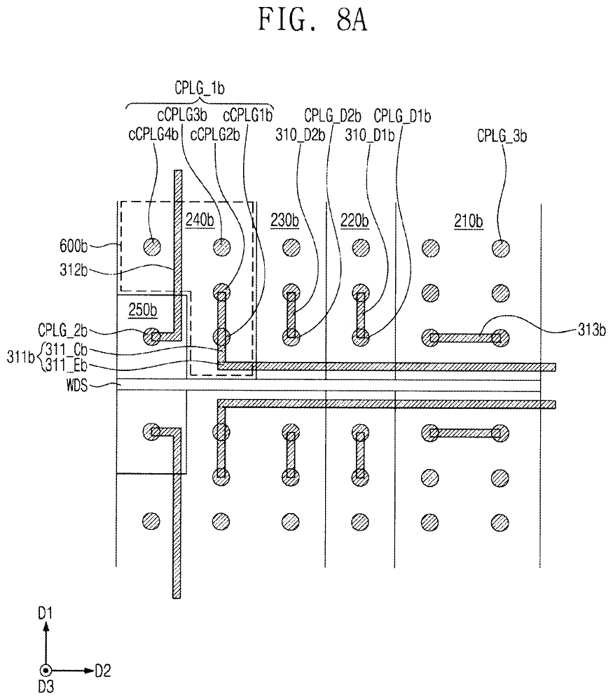

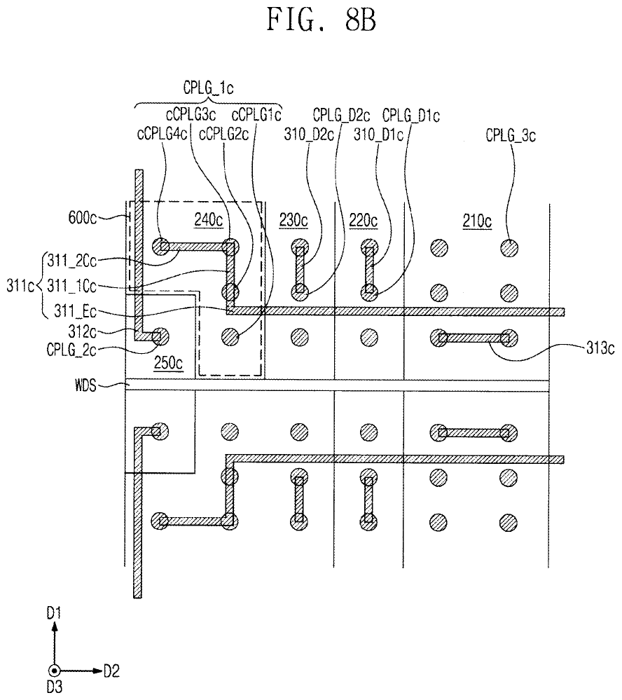

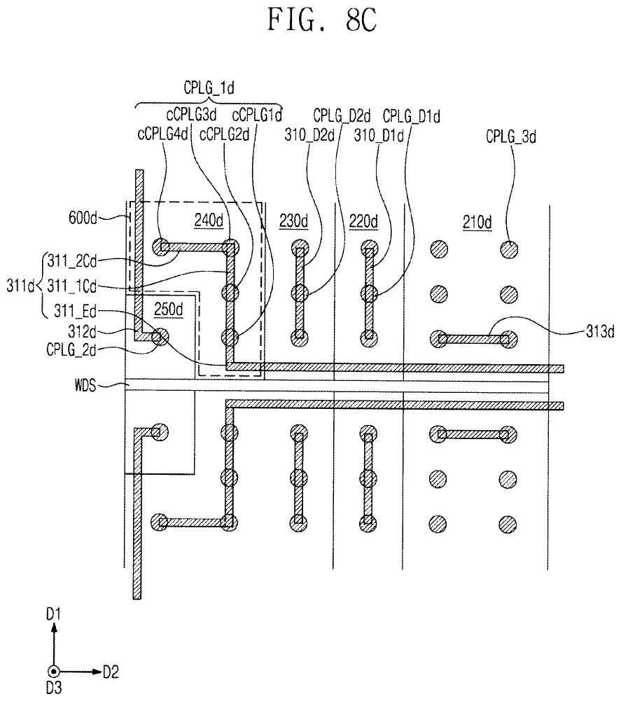

FIG. 8A is a plan view illustrating a three-dimensional semiconductor memory device according to some embodiments.

Referring to FIG. 8A, a three-dimensional semiconductor memory device may include a lower selection line 210b, a first dummy line 220b, a second dummy line 230b, a first word line 240b, and a second word line 250b. The first word line 240b may include a corner portion 600b. First contact plugs CPLG_1b may include a first corner contact plug cCPLG1b, a second corner contact plug cCPLG2b, a third corner contact plug cCPLG3b, and a fourth corner contact plug cCPLG4b.

A plurality of the first contact plugs CPLG_1b may be electrically connected to a first conductive line 311b. For example, the first conductive line 311b may include a first connection portion 311_Cb connected to the first corner contact plug cCPLG1b and the second corner contact plug cCPLG2b. The first connection portion 31_Cb of the first conductive line 311b may extend in the first direction D1 to connect the first corner contact plug cCPLG1b and the second corner contact plug cCPLG2b.

The first conductive line 311b may further include a first extension portion 311_Eb. The first extension portion 311_Eb of the first conductive line 311b may be a portion extending in the second direction D2. The first extension portion 311_Eb of the first conductive line 311b may be closer to the separation structure WDS than the first connection portion 311_Cb of the first conductive line 311b. The first conductive line 311b may not be electrically connected to the fourth corner contact plug cCPLG4b.

One of second contact plugs CPLG_2b may be electrically connected to a second conductive line 312b. The second conductive line 312b may extend in the first direction D1, but embodiments are not limited thereto.

A plurality of first dummy contact plugs CPLG_D1b may be electrically connected to a first dummy conductive line 310_D1b. For example, the first dummy conductive line 310_D1b may extend in the first direction D1 to connect two first dummy contact plugs CPLG_D1b.

Two or more of a plurality of second dummy contact plugs CPLG_D2b may be electrically connected to a second dummy conductive line 310_D2b. For example, the second dummy conductive line 310_D2b may be connected to two second dummy contact plugs CPLG_D2b adjacent to the separation structure WDS. Another or others of the second dummy contact plugs CPLG_D2b may not be connected to the second dummy conductive line 310_D2b. Two or more of a plurality of third contact plugs CPLG_3b may be electrically connected to a third conductive line 313b. The third conductive line 313b may extend in the second direction D2 to connect the third contact plugs CPLG_3b.

FIG. 8B is a plan view illustrating a three-dimensional semiconductor memory device according to some embodiments.

Referring to FIG. 8B, a three-dimensional semiconductor memory device may include a lower selection line 210c, a first dummy line 220c, a second dummy line 230c, a first word line 240c, and a second word line 250c. The first word line 240c may include a corner portion 600c. First contact plugs CPLG_1c may include a first corner contact plug cCPLG1c, a second corner contact plug cCPLG2c, a third corner contact plug cCPLG3c, and a fourth corner contact plug cCPLG4c.

A plurality of the first contact plugs CPLG_1c may be electrically connected to a first conductive line 311c. The first conductive line 311c may electrically connect the fourth corner contact plug cCPLG4c and one or more of the first to third corner contact plugs cCPLG1c, cCPLG2c and cCPLG3c.

For example, the first conductive line 311c may include a first connection portion 311_1Cc connected to the second corner contact plug cCPLG2c and the third corner contact plug cCPLG3c. The first connection portion 311_1Cc of the first conductive line 311c may extend in the first direction D1 to connect the second corner contact plug cCPLG2c and the third corner contact plug cCPLG3c. The first conductive line 311c may further include a second connection portion 311_2Cc connected to the third corner contact plug cCPLG3c and the fourth corner contact plug cCPLG4c. The second connection portion 311_2Cc of the first conductive line 311c may extend in the second direction D2 to connect the third corner contact plug cCPLG3c and the fourth corner contact plug cCPLG4c.

The first conductive line 311c may further include a first extension portion 311_Ec. The first extension portion 311_Ec of the first conductive line 311c may be a portion extending in the second direction D2. The first extension portion 311_Ec of the first conductive line 311c may be closer to the separation structure WDS than the first connection portion 311_1Cc of the first conductive line 311c. The first conductive line 311c may not be electrically connected to the first corner contact plug cCPLG1c.

One of second contact plugs CPLG_2c may be electrically connected to a second conductive line 312c. The second conductive line 312c may extend in the first direction D1, but embodiments are not limited thereto.

A plurality of first dummy contact plugs CPLG_D1c may be electrically connected to a first dummy conductive line 310_D1c. For example, the first dummy conductive line 310_Dlc may extend in the first direction D1 to connect two first dummy contact plugs CPLG_DIc.

Two or more of a plurality of second dummy contact plugs CPLG_D2c may be electrically connected to a second dummy conductive line 310_D2c. For example, the second dummy conductive line 310_D2c may not be connected to the second dummy contact plug CPLG_D2c closest to the separation structure WDS but may connect the others of the second dummy contact plugs CPLG_D2c.

Two or more of a plurality of third contact plugs CPLG_3c may be electrically connected to a third conductive line 313c. The third conductive line 313c may extend in the second direction D2 to connect the third contact plugs CPLG_3c.

FIG. 8C is a plan view illustrating a three-dimensional semiconductor memory device according to some embodiments.

Referring to FIG. 8C, a three-dimensional semiconductor memory device may include a lower selection line 210d, a first dummy line 220d, a second dummy line 230d, a first word line 240d, and a second word line 250d. The first word line 240d may include a corner portion 600d. First contact plugs CPLG_1d may include a first corner contact plug cCPLGld, a second corner contact plug cCPLG2d, a third corner contact plug cCPLG3d, and a fourth corner contact plug cCPLG4d.

A plurality of the first contact plugs CPLG_1d may be electrically connected to a first conductive line 311d. For example, the first conductive line 311d may include a first connection portion 311_1Cd connected to the first corner contact plug cCPLGld, the second corner contact plug cCPLG2d and the third corner contact plug cCPLG3d. The first connection portion 311_1Cd of the first conductive line 311d may extend in the first direction D1 to connect the first corner contact plug cCPLGld, the second corner contact plug cCPLG2d and the third corner contact plug cCPLG3d.

The first conductive line 311d may further include a second connection portion 311_2Cd connected to the third corner contact plug cCPLG3d and the fourth corner contact plug cCPLG4d. The second connection portion 311_2Cd of the first conductive line 311d may extend in the second direction D2 to connect the third corner contact plug cCPLG3d and the fourth corner contact plug cCPLG4d.

The first conductive line 311d may further include a first extension portion 311_Ed. The first extension portion 311_Ed of the first conductive line 311d may be a portion extending in the second direction D2. The first extension portion 311_Ed of the first conductive line 311d may be closer to the separation structure WDS than the first connection portion 311_1Cd of the first conductive line 311d.

One of second contact plugs CPLG_2d may be electrically connected to a second conductive line 312d. The second conductive line 312d may extend in the first direction D1, but embodiments are not limited thereto.

A plurality of first dummy contact plugs CPLG_D1d may be electrically connected to a first dummy conductive line 310_D1d. For example, the first dummy conductive line 310_D1d may extend in the first direction D1 to connect three first dummy contact plugs CPLG_Dld.

Two or more of a plurality of second dummy contact plugs CPLG_D2d may be electrically connected to a second dummy conductive line 310_D2d. For example, the second dummy conductive line 310_D2d may extend in the first direction D1 to connect three second dummy contact plugs CPLG_D2d.

By way of summation and review, embodiments provide a three-dimensional semiconductor memory device with improved reliability and integration density and an electronic system including the same.

In the three-dimensional semiconductor memory device according to the embodiments, the first conductive line may connect two or more of the first contact plugs connected to the first word line corresponding to the bottommost word line relatively vulnerable to not-open failure, and thus a failure rate of the three-dimensional semiconductor memory device may be reduced and reliability of the three-dimensional semiconductor memory device may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A three-dimensional semiconductor memory device comprising:
a gate stack structure including insulating layers, a lower selection line and word lines, the word lines including a first word line adjacent to the lower selection line and a second word line on the first word line;
a memory channel structure penetrating the gate stack structure;
a plurality of first contact plugs electrically connected to the first word line;
a plurality of second contact plugs electrically connected to the second word line;
a first conductive line connected to the plurality of first contact plugs; and
a second conductive line connected to one of the plurality of second contact plugs.

2. The three-dimensional semiconductor memory device as claimed in claim 1, wherein:
a portion of the second conductive line is connected to the one of the second contact plugs and extends in a first direction, and
a portion of the first conductive line is connected to the first contact plugs and extends in a second direction perpendicular to the first direction.

3. The three-dimensional semiconductor memory device as claimed in claim 1, further comprising:
a dummy line between the lower selection line and the first word line;
a plurality of dummy contact plugs electrically connected to the dummy line; and
a dummy conductive line connected to the plurality of dummy contact plugs.

4. The three-dimensional semiconductor memory device as claimed in claim 3, wherein the dummy line includes a plurality of dummy lines.

5. The three-dimensional semiconductor memory device as claimed in claim 1, further comprising a plurality of separation structures penetrating the gate stack structure and extending in a second direction, and
wherein at least two first contact plugs or at least two second contact plugs are located between the separation structures.

6. The three-dimensional semiconductor memory device as claimed in claim 1, wherein: the first word line includes a corner portion exposed by the second word line, and the corner portion is bent.

7. The three-dimensional semiconductor memory device as claimed in claim 6, wherein the number of the first contact plugs per unit area of the corner portion is more than the number of the second contact plugs per unit area of the second word line.

8. The three-dimensional semiconductor memory device as claimed in claim 1, further including support structures penetrating the gate stack structure.

9. The three-dimensional semiconductor memory device as claimed in claim 1, wherein the first conductive line and the second conductive line are spaced apart from each other.

10. A three-dimensional semiconductor memory device comprising:
a gate stack structure including insulating layers and word lines, the word lines including a first word line corresponding to a lowermost one of the word lines, and a second word line on the first word line;
a memory channel structure penetrating the gate stack structure;
a plurality of first contact plugs electrically connected to the first word line;
a plurality of second contact plugs electrically connected to the second word line;
a first conductive line connected to the plurality of first contact plugs; and
a second conductive line connected to one of the plurality of second contact plugs.

11. The three-dimensional semiconductor memory device as claimed in claim 10, wherein:
the first conductive line includes a first connection portion connected to the first contact plug; and a first extension portion connected to the first connection portion,
the first connection portion extends in a first direction, and the first extension portion extends in a second direction, and
the first direction intersects the second direction.

12. The three-dimensional semiconductor memory device as claimed in claim 10, wherein: the first word line includes a corner portion, and
the number of the first contact plugs per unit area of the corner portion is more than the number of the second contact plugs per unit area of the second word line.

13. The three-dimensional semiconductor memory device as claimed in claim 10, wherein the gate stack structure includes a staircase shape that becomes lower as a distance of the gate stack structure from the memory channel structure increases.

14. The three-dimensional semiconductor memory device as claimed in claim 10, further including:
a lower selection line disposed under the first word line;
a plurality of third contact plugs electrically connected to the lower selection line; and
a third conductive line connected to the plurality of third contact plugs,
wherein the second conductive line extends in a first direction,
wherein the third conductive line extends in a second direction, and
wherein the first direction intersects the second direction.

15. The three-dimensional semiconductor memory device as claimed in claim 10, wherein the first word line includes a corner portion,
wherein the first contact plugs include a first corner contact plug, a second corner contact plug, a third corner contact plug and a fourth corner contact plug, which are electrically connected to the corner portion,
wherein the first conductive line electrically connects the fourth corner contact plug and one or more of the first to third corner contact plugs,
wherein the first corner contact plug, the second corner contact plug and the third corner contact plug are arranged in a first direction,
wherein the fourth corner contact plug and the third corner contact plug are arranged in a second direction, and
wherein the first direction intersects the second direction.

16. The three-dimensional semiconductor memory device as claimed in claim 14, wherein the first conductive line, the second conductive line and the third conductive line are spaced apart from each other.

17. The three-dimensional semiconductor memory device as claimed in claim 10, further including:
a lower selection line disposed under the first word line;
a plurality of third contact plugs electrically connected to the lower selection line;
a third conductive line connected to the plurality of third contact plugs;
a dummy line between the lower selection line and the first word line;
a plurality of dummy contact plugs electrically connected to the dummy line; and
a dummy conductive line connected to the plurality of dummy contact plugs.

18. The three-dimensional semiconductor memory device as claimed in claim 17, wherein the dummy conductive line extends in a first direction and connects the dummy contact plugs, and the third conductive line extends in a second direction and connects the third contact plugs.

19. The three-dimensional semiconductor memory device as claimed in claim 10, further including:
separation structures penetrating the gate stack structure,
wherein the number of the first contact plugs between the separation structures is different from the number of the second contact plugs between the separation structures.

20. An electronic system comprising:
a main board;
a three-dimensional semiconductor memory device on the main board; and
a controller disposed on the main board and electrically connected to the semiconductor memory device,
wherein the semiconductor memory device includes:
a gate stack structure including insulating layers, a lower selection line, word lines and a dummy line, the word lines including a first word line adjacent to the lower selection line and a second word line on the first word line;
a memory channel structure penetrating the gate stack structure;
a plurality of first contact plugs electrically connected to the first word line;
a plurality of second contact plugs electrically connected to the second word line;
a plurality of third contact plugs electrically connected to the lower selection line;
a plurality of dummy contact plugs electrically connected to the dummy line;
a first conductive line connected to the plurality of first contact plugs;
a second conductive line connected to one of the plurality of second contact plugs;
a third conductive line connected to the plurality of third contact plugs; and
a dummy conductive line connected to the plurality of dummy contact plugs.
